(19) United States
(12) Patent Application Publication
(10) Pub. No.: US 2024/0076776 A1
(43) Pub. Date: Mar. 7, 2024

(54) METHODS FOR DEPOSITING ANTI-COKING PROTECTIVE COATINGS ON AEROSPACE COMPONENTS

(71) Applicant: Applied Materials, Inc., Santa Clara, CA (US)

(72) Inventors: Sukti CHATTERJEE, San Jose, CA (US); David Alexander BRITZ, Los Gatos, CA (US)

(21) Appl. No.: 17/767,392

(22) PCT Filed: Jul. 17, 2020
(86) PCT No.: PCT/US20/42444

§ 371 Date: Apr. 7, 2022

Related U.S. Application Data
(60) Provisional application No. 62/912,513, filed on Oct. 8, 2019.

(51) Int. Cl. C23C 16/455; C23C 16/02; C23C 16/40; C23C 28/04

(52) U.S. Cl. CPC C23C 16/45555; C23C 16/0272; C23C 16/403; C23C 16/45527; C23C 28/042

(57) ABSTRACT

Embodiments of the present disclosure generally relate to protective coatings on an aerospace component and methods for depositing the protective coatings. The protective coating can be anti-coking coatings to reduce or suppress coke formation when the aerospace component is heated in the presence of a fuel. In one or more embodiments, a method for depositing a protective coating on an aerospace component includes depositing an optional barrier layer on a surface of the aerospace component and depositing a catalytic oxidation layer on the barrier layer and/or directly on the aerospace component. The barrier layer can be or include aluminum oxide, magnesium-doped aluminum oxide, dopants thereof, or any combination thereof. The catalytic oxidation layer can be or include cerium oxide or one or more oxygen storage materials.

### CROSS-REFERENCE TO RELATED APPLICATIONS

This application is a national stage filing of International Appl. No. PCT/US2020/42444, filed Jul. 17, 2020, which claims benefit to U.S. Prov. Appl. No. 62/912,513, filed on Oct. 8, 2019, which are herein incorporated by reference in their entirety.

### BACKGROUND

### Field

Embodiments of the present disclosure generally relate to deposition processes, and in particular to vapor deposition processes for depositing films on aerospace components.

### Description of the Related Art

Coking is a known problem in fuel nozzles due to high temperatures (e.g., about 600° C. to about 1,000° C.), a fuel-rich environment in the nozzle and in the combustor, and a metallic surface that can nucleate the deposition of carbon. Because fuel nozzles are complex in geometry and have high aspect ratio passages, it is difficult to coat those passages with a coating that resists coking.

Current approaches reducing coking in the turbine industry are largely based on mechanical techniques, such as control the temperature of the part, control fuel flows, or adding inserts. Ceramic inserts are used at the exit of the fuel nozzle, as are thermal barrier-type coatings of ceramic materials formed by PVD and/or thermal sprayed process. However, ceramics are expensive and prone to cracking. Ceramics and thermal barrier coatings are not suitable to high aspect ratio, complex structures. Fuel additives, such as antioxidants or detergents, can be used to reduce the coking of fuel nozzles. However, such fuel additives only reduce the build-up of coke and the fuel nozzle inevitably builds up a coking layer which reduces or eliminates fuel flow.

Therefore, improved protective coatings and methods for depositing the protective coatings on aerospace components are needed.

### SUMMARY

Embodiments of the present disclosure generally relate to protective coatings on aerospace components and methods for depositing the protective coatings. The protective coatings are also anti-coking coatings to reduce or suppress coke formation when the aerospace component is heated in the presence of a fuel in a reducing environment. In one or more embodiments, a method for depositing a protective coating on an aerospace component includes depositing an optional barrier layer on a surface of the aerospace component and depositing a catalytic oxidation layer on the barrier layer and/or directly on the aerospace component. The barrier layer can be or include aluminum oxide, magnesium-doped aluminum oxide, dopants thereof, or any combination thereof. The catalytic oxidation layer can be or include cerium oxide or one or more oxygen storage materials.

In other embodiments, a method for depositing a protective coating on an aerospace component include depositing a catalytic oxidation layer containing cerium oxide on a surface of the aerospace component by an atomic layer deposition (ALD) process. The aerospace component can be or include one or more of a fuel nozzle, a combustor liner, a combustor shield, a heat exchanger, a fuel line, a fuel valve, or any combination thereof. In some examples, the surface of the aerospace component has an aspect ratio of about 5 to about 1,000. The catalytic oxidation layer can have a thickness of about 10 nm to about 500 nm.

In some embodiments, an aerospace component which has a protective coating disposed on a surface of the aerospace component. The protective coating contains a barrier layer and a catalytic oxidation layer. The barrier layer contains aluminum oxide and is disposed on the surface of the aerospace component. The catalytic oxidation layer contains cerium oxide and is disposed on the barrier layer.

### DETAILED DESCRIPTION

Embodiments of the present disclosure generally relate to protective coatings on aerospace components and methods for depositing the protective coatings. The protective coatings are also anti-coking coatings to reduce or suppress coke formation when the aerospace component is heated in the presence of a fuel. The protective coatings can be or include monolayer films and/or multi-layer films. In one or more examples, the protective coating contains one or more barrier layers deposited on the surface of the aerospace component and one or more catalytic oxidation layers deposited on the barrier layer. In other examples, the protective coating contains one or more catalytic oxidation layers deposited directly on the surface of the aerospace component.

In some embodiments, the aerospace component as described and discussed herein can be or include one or more of a fuel nozzle, a combustor liner, a combustor shield, a heat exchanger, a fuel line, a fuel valve, any other part or portion that is exposed to a fuel (e.g., aviation fuel or jet fuel) or any combination thereof. In other embodiments, the aerospace components as described and discussed herein can be or include one or more turbine blades, turbine vanes, ribs, fins, pin fins, or any other aerospace component or part that can benefit from having protective coating deposited thereon. The protective coatings can be deposited or otherwise formed on interior surfaces and/or exterior surfaces of the aerospace components.

### Clean Process

Prior to producing the protective coating, the aerospace component can optionally be exposed to one or more cleaning processes. One or more contaminants are removed from the aerospace component to produce the cleaned surface during the cleaning process. The contaminant can be or include oxides, organics or organic residues, carbon, oil, soil, particulates, debris, and/or other contaminants, or any combination thereof. These contaminants are removed prior to producing the protective coating on the aerospace component.

The cleaning process can be or include one or more basting or texturing processes, vacuum purges, solvent clean, acid clean, basic or caustic clean, wet clean, ozone clean, plasma clean, sonication, or any combination thereof. Once cleaned and/or textured, the subsequently deposited protective coating has stronger adhesion to the cleaned surfaces or otherwise altered surfaces of the aerospace component than if otherwise not exposed to the cleaning process.

In one or more examples, the surfaces of the aerospace component can be blasted with or otherwise exposed to beads, sand, carbonate, or other particulates to remove oxides and other contaminates therefrom and/or to provide texturing to the surfaces of the aerospace component. In some examples, the aerospace component can be placed into a chamber within a pulsed push-pull system and exposed to cycles of purge gas or liquid (e.g., N₂, Ar, He, one or more alcohols (methanol, ethanol, propanol, and/or others), water, or any combination thereof) and vacuum purges to remove debris from small holes on the aerospace component. In other examples, the surfaces of the aerospace component can be exposed to hydrogen plasma, oxygen or ozone plasma, and/or nitrogen plasma, which can be generated in a plasma chamber or by a remote plasma system.

In some examples, such as for organic removal or oxide removal, the surfaces of the aerospace component can be exposed to a hydrogen plasma, then degassed, then exposed to ozone treatment. In other examples, such as for organic removal, the surfaces of the aerospace component can be exposed to a wet clean that includes: soaking in an alkaline degreasing solution, rinsing, exposing the surfaces to an acid clean (e.g., sulfuric acid, phosphoric acid, hydrochloric acid, hydrofluoric acid, or any combination thereof), rinsing, and exposing the surfaces deionized water sonication bath. In some examples, such as for oxide removal, the surfaces of the aerospace component can be exposed to a wet clean that includes: exposing the surfaces to a dilute acid solution (e.g., acetic acid hydrochloric acid, hydrofluoric acid, or combinations thereof), rinsing, and exposing the surfaces deionized water sonication bath. In one or more examples, such as for particle removal, the surfaces of the aerospace component can be exposed to sonication (e.g., megasonication) and/or a supercritical fluid (carbon dioxide, water, one or more alcohols) wash, followed by exposing to cycles of purge gas or liquid (e.g., N₂, Ar, He, one or more alcohols, H₂O, or any combination thereof) and vacuum purges to remove particles from and dry the surfaces. In some examples, the aerospace component can be exposed to heating or drying processes, such as heating the aerospace component to a temperature of about 50° C., about 65° C., or about 80° C. to about 100° C., about 120° C., or about 150° C. and exposing to surfaces to the purge gas. The aerospace component can be heated in an oven or exposed to lamps for the heating or drying processes. Optionally, hot gas can be forced through internal passages to accelerate drying. Optionally, the component can be dried in reduced atmosphere without heating or with heating.

In various embodiments, the cleaned surface of the aerospace component can be one or more interior surfaces and/or one or more exterior surfaces of the aerospace component. The cleaned surface of the aerospace component can be or include one or more material, such as nickel, nickel superalloy, stainless steel, cobalt, chromium, molybdenum, iron, titanium, alloys thereof, or any combination thereof. In one or more examples, the cleaned surface is within a cavity of the aerospace component and the cavity can have an aspect ratio of greater than 1, such as about 5 to about 1,000, such as about 20 to about 500.

In some examples, the protective coating has a thickness of about 10 nm to about 5,000 nm, about 100 nm to about 4,000 nm, or about 500 nm to about 2,000 nm. Also, the protective coating can have a thickness variation of less than 200%, less than 100%, less than 25%, less than 5%, or less than 0.5%.

### Barrier Layer

The protective coating reduces or suppresses coke formation when the aerospace component is heated in the presence of a fuel, such as an aviation fuel, jet fuel, kerosene, or the like. In one or more embodiments, the protective coating contains one or more barrier layers deposited on the surface of the aerospace component and one or more catalytic oxidation layers deposited on the barrier layer. The barrier layer can be or include one or more materials, such as aluminum oxide, magnesium-doped aluminum oxide, aluminum nitride, aluminum oxynitride, silicon oxide, silicon nitride, silicon oxynitride, chromium oxide, tantalum oxide, tantalum nitride, tantalum oxynitride, alloys thereof, dopants thereof, or any combination thereof.

In one or more embodiments, a method for depositing the barrier layer on the surface of the aerospace component includes sequentially exposing the aerospace component to an aluminum precursor, one or more oxidizing agents, and/or optionally one or more reagents or dopant sources to form an aluminum oxide material or layer on a surface the aerospace component by an atomic layer deposition (ALD) process. In some examples, the reactant, precursor, reagent, or dopant source can be or contain a magnesium source or magnesium precursor. The oxidizing agent can be or contain water (e.g., steam), ozone, oxygen (O₂), atomic oxygen, nitrous oxide, one or more peroxides (e.g., hydrogen peroxide, other inorganic peroxides, organic peroxides), one or more alcohols (e.g., methanol, ethanol, propanol, or higher alcohols), plasmas thereof, or any combination thereof.

The aerospace component can be exposed to a first precursor (e.g., aluminum precursor) and a first reactant (e.g., oxidizing agent) to form the first deposited layer (e.g., aluminum oxide) on the aerospace component by a vapor deposition process. The vapor deposition process can be an ALD process, a plasma-enhanced ALD (PE-ALD) process, a thermal chemical vapor deposition (CVD) process, a plasma-enhanced CVD (PE-CVD) process, a pulsed-CVD process, or any combination thereof.

In one or more embodiments, the vapor deposition process is an ALD process and the method includes sequentially exposing the surface of the aerospace component to the first precursor and the first reactant to form the barrier layer or the first deposited layer. For example, the ALD process includes sequentially exposing the aerospace component to the aluminum precursor and the oxidizing agent to deposit or otherwise form aluminum oxide within the barrier layer or the first deposited layer. Each cycle of the ALD process includes exposing the surface of the aerospace component to the first precursor, conducting a pump-purge, exposing the aerospace component to the first reactant, and conducting a pump-purge to form the barrier layer or the first deposited layer. The order of the first precursor and the first reactant can be reversed, such that the ALD cycle includes exposing the surface of the aerospace component to the first reactant, conducting a pump-purge, exposing the aerospace component to the first precursor, and conducting a pump-purge to form the barrier layer or the first deposited layer.

In some examples, during each ALD cycle, the aerospace component is exposed to the first precursor for about 0.1 seconds to about 10 seconds, the first reactant for about 0.1 seconds to about 10 seconds, and the pump-purge for about 0.5 seconds to about 30 seconds. In other examples, during each ALD cycle, the aerospace component is exposed to the first precursor for about 0.5 seconds to about 3 seconds, the first reactant for about 0.5 seconds to about 3 seconds, and the pump-purge for about 1 second to about 10 seconds.

Each ALD cycle is repeated from 2, 3, 4, 5, 6, 8, about 10, about 12, or about 15 times to about 18, about 20, about 25, about 30, about 40, about 50, about 65, about 80, about 100, about 120, about 150, about 200, about 250, about 300, about 350, about 400, about 500, about 800, about 1,500, about 2,000, about 2,500, about 3,000, or more times to form the barrier layer or the first deposited layer. For example, each ALD cycle is repeated from 2 times to about 3,000 times, 2 times to about 2,000 times, 2 times to about 1,500 times, 2 times to about 1,000 times, 2 times to about 800 times, 2 times to about 500 times, 2 times to about 300 times, 2 times to about 250 times, 2 times to about 200 times, 2 times to about 150 times, 2 times to about 120 times, 2 times to about 100 times, 2 times to about 80 times, 2 times to about 50 times, 2 times to about 30 times, 2 times to about 20 times, 2 times to about 15 times, 2 times to about 10 times, 2 times to 5 times, about 8 times to about 1,000 times, about 8 times to about 800 times, about 8 times to about 500 times, about 8 times to about 300 times, about 8 times to about 250 times, about 8 times to about 200 times, about 8 times to about 150 times, about 8 times to about 120 times, about 8 times to about 100 times, about 8 times to about 80 times, about 8 times to about 50 times, about 8 times to about 30 times, about 8 times to about 20 times, about 8 times to about 15 times, about 8 times to about 10 times, about 20 times to about 1,000 times, about 20 times to about 800 times, about 20 times to about 500 times, about 20 times to about 300 times, about 20 times to about 250 times, about 20 times to about 200 times, about 20 times to about 150 times, about 20 times to about 120 times, about 20 times to about 100 times, about 20 times to about 80 times, about 20 times to about 50 times, about 20 times to about 30 times, about 50 times to about 1,000 times, about 50 times to about 500 times, about 50 times to about 350 times, about 50 times to about 300 times, about 50 times to about 250 times, about 50 times to about 150 times, or about 50 times to about 100 times to form the barrier layer or the first deposited layer.

In other embodiments, the vapor deposition process is a CVD process and the method includes simultaneously exposing the aerospace component to the first precursor and the first reactant to form the first deposited layer. During an ALD process or a CVD process, each of the first precursor and the first reactant can independent include one or more carrier gases. One or more purge gases can be flowed across the aerospace component and/or throughout the processing chamber in between the exposures of the first precursor and the first reactant. In some examples, the same gas may be used as a carrier gas and a purge gas. Exemplary carrier gases and purge gases can independently be or include one or more of nitrogen (N₂), argon, helium, neon, hydrogen (H₂), or any combination thereof.

The barrier layer or the first deposited layer can have a thickness of about 0.1 nm, about 0.2 nm, about 0.3 nm, about 0.4 nm, about 0.5 nm, about 0.8 nm, about 1 nm, about 2 nm, about 3 nm, about 5 nm, about 8 nm, about 10 nm, about 12 nm, about 15 nm, about 18 nm, about 20 nm, about 25 nm, about 30 nm, about 40 nm, about 50 nm, or about 60 nm to about 70 nm, about 80 nm, about 100 nm, about 120 nm, about 150 nm, about 200 nm, about 250 nm, about 300 nm, about 400 nm, or about 500 nm. For example, the barrier layer or the first deposited layer can have a thickness of about 0.1 nm to about 500 nm, about 0.1 nm to about 300 nm, about 0.1 nm to about 250 nm, about 0.1 nm to about 200 nm, about 0.1 nm to about 150 nm, about 0.2 nm to about 150 nm, about 0.2 nm to about 120 nm, about 0.2 nm to about 100 nm, about 0.2 nm to about 80 nm, about 1 nm to about 500 nm, about 1 nm to about 300 nm, about 1 nm to about 250 nm, about 1 nm to about 200 nm, about 1 nm to about 150 nm, about 1 nm to about 120 nm, about 1 nm to about 100 nm, about 1 nm to about 80 nm, about 1 nm to about 50 nm, about 1 nm to about 40 nm, about 1 nm to about 30 nm, about 1 nm to about 20 nm, about 1 nm to about 10 nm, about 1 nm to about 5 nm, about 1 nm to about 3 nm, about 5 nm to about 250 nm, about 10 nm to about 500 nm, about 10 nm to about 300 nm, about 10 nm to about 250 nm, about 10 nm to about 200 nm, about 10 nm to about 150 nm, about 10 nm to about 120 nm, about 10 nm to about 100 nm, about 10 nm to about 80 nm, about 10 nm to about 50 nm, about 10 nm to about 40 nm, about 10 nm to about 30 nm, about 10 nm to about 20 nm, about 10 nm to about 15 nm, about 50 nm to about 500 nm, about 50 nm to about 300 nm, about 50 nm to about 250 nm, about 50 nm to about 200 nm, about 50 nm to about 150 nm, about 50 nm to about 120 nm, about 50 nm to about 100 nm, about 50 nm to about 80 nm, about 60 nm to about 100 nm, or about 60 nm to about 80 nm.

In one or more embodiments, the first precursor can be or contain one or more ALD or CVD precursors, such as one or more aluminum precursors, one or more magnesium precursors, one or more chromium precursors, and/or one or more hafnium precursors. Exemplary magnesium precursors can be or include (Cp)₂Mg, (MeCp)₂Mg, (Me₅Cp)₂Mg, ⁱPr₂Mg, ^{t}Bu₂Mg, adducts thereof, solutions thereof, or any combination thereof. The first reactant contains one or more oxidizing agents, one or more nitriding agents, one or more reducing agents, one or more silicon precursors, one or more carbon precursors, or any combination thereof. In some examples, the first deposited layer is an aluminum-containing layer which can be or include metallic aluminum, aluminum oxide, doped-aluminum oxide (e.g., magnesium doped-aluminum oxide), aluminum nitride, aluminum silicide, aluminum carbide, or any combination thereof.

The aluminum precursor can be or include one or more of aluminum alkyl compounds, one or more of aluminum alkoxy compounds, one or more of aluminum acetylacetonate compounds, substitutes thereof, complexes thereof, abducts thereof, salts thereof, or any combination thereof. For example, the aluminum precursor can be or include one or more of tris(alkyl) aluminums, tris(alkoxy) aluminums, aluminum diketonates, complexes thereof, abducts thereof, salts thereof, or any combination thereof. Exemplary aluminum precursors can be or include trimethylaluminum, triethylaluminum, tripropylaluminum, tributylaluminum, trimethoxyaluminum, triethoxyaluminum, tripropoxyaluminum, tributoxyaluminum, aluminum acetylacetonate (Al(acac)₃, also known as, tris(2,4-pentanediono) aluminum), aluminum hexafluoroacetylacetonate (Al(hfac)₃), trisdipivaloylmethanatoaluminum (DPM₃Al; (C₁₁H₁₉O₂)₃Al), isomers thereof, complexes thereof, abducts thereof, salts thereof, or any combination thereof.

In one or more examples, the precursor is or contains one or more aluminum alkyl compounds, such as trimethyl aluminum (TMA). The aluminum alkyl compound (e.g., TMA) has a purity of greater than 95 weight percent (wt %), greater than 97 wt %, or greater than 99 wt %, such as about 99.3 wt %, about 99.5 wt %, about 99.7 wt %, or about 99.9 wt % to about 99.95 wt %, about 99.99 wt %, about 99.995 wt %, about 99.999 wt %, about 99.9999 wt %, or greater. In one or more examples, the aluminum alkyl compound (e.g., TMA) has a purity of 99.5 wt % or greater, such as about 99.9 wt % to about 99.999 wt %.

### Catalytic Oxidation Layer

The catalytic oxidation layer can be or include one or more materials, such as cerium oxide, one or more doped cerium oxides, and/or one or more oxygen storage materials (OSMs). Exemplary oxygen storage materials can be or include zirconium oxide, calcium aluminum manganese oxide, barium yttrium manganese oxide, lanthanum rhodium manganese oxide, lutetium iron oxide, yttrium barium cobalt oxide, lanthanum oxide sulfate, dopants thereof, or any combination thereof. In one or more examples, the catalytic oxidation layer contains cerium oxide and one or more dopants. Exemplary dopants within the doped cerium oxides can be or include one or more of gadolinium, manganese, strontium, cobalt, copper, aluminum, alloys thereof, oxides thereof, or any combination thereof

The aerospace component can be exposed to a second precursor (e.g., cerium precursor) and a second reactant (e.g., oxidizing agent) to form the second deposited layer (e.g., catalytic oxidation layer containing cerium oxide, dope-cerium oxide, or an OSM) on the barrier layer and/or a surface of the aerospace component by a vapor deposition process. The vapor deposition process can be a thermal ALD process, a PE-ALD process, a thermal CVD process, a PE-CVD process, a pulsed-CVD process, or any combination thereof. Exemplary oxidizing agents can be or contain water (e.g., steam), ozone, oxygen (O₂), atomic oxygen, nitrous oxide, one or more peroxides (e.g., hydrogen peroxide, other inorganic peroxides, organic peroxides), one or more alcohols (e.g., methanol, ethanol, propanol, or higher alcohols), plasmas thereof, or any combination thereof.

In one or more examples, the second precursor can be or include one or more cerium precursors, and/or one or more other precursors. During the ALD process, each of the second precursor and the second reactant can independent include one or more carrier gases. One or more purge gases can be flowed across the aerospace component and/or throughout the processing chamber in between the exposures of the second precursor and the second reactant. In some examples, the same gas may be used as a carrier gas and a purge gas. Exemplary carrier gases and purge gases can independently be or include one or more of nitrogen (N₂), argon, helium, neon, hydrogen (H₂), or any combination thereof.

Each cycle of the ALD process includes exposing the aerospace component to the second precursor, conducting a pump-purge, exposing the aerospace component to the second reactant, and conducting a pump-purge to form the catalytic oxidation layer or the second deposited layer. The order of the second precursor and the second reactant can be reversed, such that the ALD cycle includes exposing the surface of the aerospace component to the second reactant, conducting a pump-purge, exposing the aerospace component to the second precursor, and conducting a pump-purge to form the second deposited layer. In some examples, the ALD process includes sequentially exposing the barrier layer and/or the aerospace component to one or more cerium precursors, a purge gas, one or more oxidizing agents, and the purge gas during an ALD cycle. The ALD cycle is repeated to deposit or otherwise form cerium oxide within the catalytic oxidation layer or the second deposited layer.

In one or more examples, during each ALD cycle, the aerospace component is exposed to the second precursor for about 0.1 seconds to about 10 seconds, the second reactant for about 0.1 seconds to about 10 seconds, and the pump-purge for about 0.5 seconds to about 30 seconds. In other examples, during each ALD cycle, the aerospace component is exposed to the second precursor for about 0.5 seconds to about 3 seconds, the second reactant for about 0.5 seconds to about 3 seconds, and the pump-purge for about 1 second to about 10 seconds.

Each ALD cycle is repeated from 2, 3, 4, 5, 6, 8, about 10, about 12, or about 15 times to about 18, about 20, about 25, about 30, about 40, about 50, about 65, about 80, about 100, about 120, about 150, about 200, about 250, about 300, about 350, about 400, about 500, about 800, about 1,000, about 1,500, about 2,000, about 2,500, about 3,000, or more times to form the catalytic oxidation layer or the second deposited layer. For example, each ALD cycle is repeated from 2 times to about 3,000 times, 2 times to about 2,500 times, 2 times to about 2,000 times, 2 times to about 1,500 times, 2 times to about 1,000 times, 2 times to about 800 times, 2 times to about 500 times, 2 times to about 300 times, 2 times to about 250 times, 2 times to about 200 times, 2 times to about 150 times, 2 times to about 120 times, 2 times to about 100 times, 2 times to about 80 times, 2 times to about 50 times, 2 times to about 30 times, 2 times to about 20 times, 2 times to about 15 times, 2 times to about 10 times, 2 times to 5 times, about 8 times to about 1,000 times, about 8 times to about 800 times, about 8 times to about 500 times, about 8 times to about 300 times, about 8 times to about 250 times, about 8 times to about 200 times, about 8 times to about 150 times, about 8 times to about 120 times, about 8 times to about 100 times, about 8 times to about 80 times, about 8 times to about 50 times, about 8 times to about 30 times, about 8 times to about 20 times, about 8 times to about 15 times, about 8 times to about 10 times, about 20 times to about 1,000 times, about 20 times to about 800 times, about 20 times to about 500 times, about 20 times to about 300 times, about 20 times to about 250 times, about 20 times to about 200 times, about 20 times to about 150 times, about 20 times to about 120 times, about 20 times to about 100 times, about 20 times to about 80 times, about 20 times to about 50 times, about 20 times to about 30 times, about 50 times to about 1,000 times, about 50 times to about 500 times, about 50 times to about 350 times, about 50 times to about 300 times, about 50 times to about 250 times, about 50 times to about 150 times, or about 50 times to about 100 times to form the catalytic oxidation layer or the second deposited layer.

The catalytic oxidation layer or the second deposited layer can have a thickness of about 0.1 nm, about 0.2 nm, about 0.3 nm, about 0.4 nm, about 0.5 nm, about 0.8 nm, about 1 nm, about 2 nm, about 3 nm, about 5 nm, about 8 nm, about 10 nm, about 12 nm, about 15 nm, about 18 nm, about 20 nm, about 25 nm, about 30 nm, about 40 nm, about 50 nm, or about 60 nm to about 70 nm, about 80 nm, about 100 nm, about 120 nm, about 150 nm, about 200 nm, about 250 nm, about 300 nm, about 400 nm, or about 500 nm. For example, the catalytic oxidation layer or the second deposited layer can have a thickness of about 0.1 nm to about 500 nm, about 0.1 nm to about 300 nm, about 0.1 nm to about 250 nm, about 0.1 nm to about 200 nm, about 0.1 nm to about 150 nm, about 0.2 nm to about 150 nm, about 0.2 nm to about 120 nm, about 0.2 nm to about 100 nm, about 0.2 nm to about 80 nm, about 1 nm to about 500 nm, about 1 nm to about 300 nm, about 1 nm to about 250 nm, about 1 nm to about 200 nm, about 1 nm to about 150 nm, about 1 nm to about 120 nm, about 1 nm to about 100 nm, about 1 nm to about 80 nm, about 1 nm to about 50 nm, about 1 nm to about 40 nm, about 1 nm to about 30 nm, about 1 nm to about 20 nm, about 1 nm to about 10 nm, about 1 nm to about 5 nm, about 1 nm to about 3 nm, about 5 nm to about 250 nm, about 10 nm to about 500 nm, about 10 nm to about 300 nm, about 10 nm to about 250 nm, about 10 nm to about 200 nm, about 10 nm to about 150 nm, about 10 nm to about 120 nm, about 10 nm to about 100 nm, about 10 nm to about 80 nm, about 10 nm to about 50 nm, about 10 nm to about 40 nm, about 10 nm to about 30 nm, about 10 nm to about 20 nm, about 10 nm to about 15 nm, about 50 nm to about 500 nm, about 50 nm to about 300 nm, about 50 nm to about 250 nm, about 50 nm to about 200 nm, about 50 nm to about 150 nm, about 50 nm to about 120 nm, about 50 nm to about 100 nm, about 50 nm to about 80 nm, about 60 nm to about 100 nm, or about 60 nm to about 80 nm.

In one or more embodiments, the cerium precursor can be or include one or more cerium β-diketonate compounds, one or more cerium cyclopentadienyl compounds, one or more cerium alkoxide compounds, one or more cerium amide compounds, one or more cerium acetamidinate compounds, adducts thereof, or any combination thereof.

In some examples, the cerium precursor can be or include one or more cerium β-diketonate compounds. The cerium β-diketonate compound contains a cerium atom and at least one, two, three, or four β-diketonate ligands and can optionally have one or more other types of ligands. One exemplary β-diketonate ligand is 2,2,6,6-tetramethyl-3,5-heptanedione, which is also known as “thd”. Exemplary cerium β-diketonate compounds which contain thd can be or include Ce(thd)₄, Ce(thd)₃, Ce(thd)₃(phen), any adducts thereof, or any combination thereof. The “phen” ligand is also known as 1,10-phenanthroline. See Table 1 for a listing of the full chemical names of some exemplary cerium β-diketonate compounds.

In some examples, the cerium precursor can be or include one or more cerium cyclopentadienyl compounds. The cerium cyclopentadienyl compound contains a cerium atom and at least one, two, three, or four cyclopentadienyl ligands and can optionally have one or more other types of ligands. Exemplary cerium cyclopentadienyl compounds can be or include (Cp)₃Ce, (MeCp)₃Ce, (EtCp)₃Ce, (PrCp)₃Ce, (BuCp)₃Ce, any adduct thereof, or any combination thereof. The cyclopentadienyl ligand, also known as “Cp”, can be unsubstituted or can be substituted with one, two, or more groups, such as alkyl groups and the various isomers of the alkyl groups. For example, the MeCp ligand is methylcyclopentadienyl, the EtCp ligand is ethylcyclopentadienyl, the PrCp ligand is propylcyclopentadienyl, where Pr includes n-propyl and/or iso-propyl, and the BuCp ligand is butylcyclopentadienyl, where Bu includes n-butyl, sec-butyl, and/or tert-butyl. See Table 1 for a listing of the full chemical names of some exemplary cerium cyclopentadienyl compounds.

In some examples, the cerium precursor can be or include one or more cerium alkoxide compounds. The cerium alkoxide compound contains a cerium atom and at least one, two, three, or four alkoxide ligands and can optionally have one or more other types of ligands. Exemplary cerium alkoxide compounds can be or include Ce(mmp)₄ (cerium tetra(1-methoxy-2-methyl-2-propanolate)), Ce(dmap)₄ (cerium tetra(1-(dimethylamino)propan-2-olate)), Ce(dmop)₄ (cerium tetra(2-(4,4-dimethyl-4,5-dihydrooxazol-2-yl)propan-2-olate)), an adduct thereof, or any combination thereof. See Table 1 for a listing of the full chemical names of some exemplary cerium alkoxide compounds.

In some examples, the cerium precursor can be or include one or more cerium amide compounds or cerium acetamidinate compounds. The cerium amide compound and the cerium acetamidinate compound contains a cerium atom and at least one, two, three, or four nitrogen-containing ligands, such as an amide, an amine, and/or an acetamidinate. The cerium amide compound and the cerium acetamidinate can also have one or more other types of ligands, such as β-diketonate, cyclopentadienyl, alkoxide, or other ligands. An exemplary cerium amide compound can be (hmdsa)₃Ce and an exemplary cerium acetamidinate compound can be (′PrCp)₂Ce(N-′Pr-amd). The “hmdsa” ligand is also known as hexamethyldisilamide. The “N-′Pr-amd” ligand is also known as diisopropylacetamidinate. See Table 1 for a listing of the full chemical names of some exemplary cerium amide compounds and the cerium acetamidinate compounds, which are exemplary cerium precursors.

TABLE 1

| | Cerium Compound | Formula |
|---|---|---|
| 1 | tetrakis(2,2,6,6-tetramethyl-3,5-heptanedionato) | Ce(thd)₄ |
| | cerium | |
| 2 | tris(2,2,6,6-tetramethyl-3,5-heptanedionato) | Ce(thd)₃ |
| | cerium | |
| 3 | tris(2,2,6,6-tetramethyl-3,5-heptanedionato) | Ce(thd)₃(phen) |
| | (1,10-phenanthroline) cerium | |
| 4 | tris(cyclopentadienyl) cerium | (Cp)₃Ce |
| 5 | tris(methylcyclopentadienyl) cerium | (MeCp)₃Ce |
| 6 | tris(ethylcyclopentadienyl) cerium | (EtCp)₃Ce |
| 7 | tris(propylcyclopentadienyl) cerium | (PrCp)₃Ce |
| 8 | tris(butylcyclopentadienyl) cerium | (BuCp)₃Ce |
| 9 | cerium tetra(1-methoxy-2-methyl-2- | Ce(mmp)₄ |
| | propanolate) | |
| 10 | cerium tetra(1-(dimethylamino)propan-2-olate) | Ce(dmap)₄ |
| 11 | cerium tetra(2-(4,4-dimethyl-4,5- | Ce(dmop)₄ |
| | dihydrooxazol-2-yl)propan-2-olate) | |
| 12 | tris(hexamethyldisilamide) cerium | (hmdsa)₃Ce |
| 13 | bis(isopropylcyclopentadienyl) | (ⁱPrCp)₂Ce(N—ⁱPr- |
| | (diisopropylacetamidinate) cerium | amd) |

In one or more embodiments, the cerium precursor can be or include one or more solvents. The solvent can be or include one or more of toluene, benzene, tetrahydrofuran, ethyl ether or other ethers, one or more alkanes (e.g., butane, pentane, hexane, heptane, and/or octane), one or more alcohols (e.g., methanol, ethanol, propanol, and/or butanol), or any combination thereof.

Throughout the ALD process, one or more cerium precursors, one or more oxidizing agents, and a purge gas and/or carrier gas are sequentially introduced into the processing chamber. During each ALD cycle, the chamber surfaces and/or the chamber components are sequentially exposed to the one or more cerium precursors and the one or more oxidizing agents. The oxidizing agent can be or include one or more of water, oxygen (O₂), atomic oxygen, ozone, nitrous oxide, one or more peroxides (e.g., hydrogen peroxide and/or an organic peroxide), plasmas thereof, or any combination thereof. The purge gas and/or carrier gas can be or include one or more of nitrogen (N₂), argon, helium, hydrogen (H₂), oxygen (O₂), or any combination thereof.

The aerospace component is heated to a temperature of about 30° C., about 50° C., about 80° C., about 100° C., or about 120° C. to about 150° C., about 180° C., about 200° C., about 250° C., about 300° C., about 350° C., about 400° C., about 500° C., or greater during the ALD process. For example, the aerospace component is heated to a temperature of about 30° C. to about 500° C., about 30° C. to about 400° C., about 30° C. to about 350° C., about 30° C. to about 300° C., about 30° C. to about 250° C., about 30° C. to about 200° C., about 30° C. to about 150° C., about 30° C. to about 100° C., about 50° C. to about 500° C., about 50° C. to about 400° C., about 50° C. to about 350° C., about 50° C. to about 300° C., about 50° C. to about 250° C., about 50° C. to about 200° C., about 50° C. to about 150° C., about 50° C. to about 100° C., about 100° C. to about 500° C., about 100° C. to about 400° C., about 100° C. to about 350° C., about 100° C. to about 300° C., about 100° C. to about 250° C., about 100° C. to about 200° C., about 100° C. to about 150° C., about 150° C. to about 500° C., about 150° C. to about 400° C., about 150° C. to about 350° C., about 150° C. to about 300° C., about 150° C. to about 250° C., or about 150° C. to about 200° C. during the ALD process.

In one or more embodiments, the vapor deposition process is an ALD process and the method includes sequentially exposing the aerospace component to the cerium precursor and the oxidizing agent to form the cerium oxide layer. Each cycle of the ALD process includes exposing the surface of the aerospace component to the cerium precursor, conducting a pump-purge, exposing the aerospace component to the oxidizing agent, and conducting a pump-purge to form the cerium oxide layer. The order of the cerium precursor and the oxidizing agent can be reversed, such that the ALD cycle includes exposing the surface of the aerospace component to the oxidizing agent, conducting a pump-purge, exposing the aerospace component to the cerium precursor, and conducting a pump-purge to form the cerium oxide layer.

In some examples, during each ALD cycle, the aerospace component is exposed to the cerium precursor for about 0.1 seconds to about 10 seconds, the oxidizing agent for about 0.1 seconds to about 10 seconds, and the pump-purge for about 0.5 seconds to about 30 seconds. In other examples, during each ALD cycle, the aerospace component is exposed to the cerium precursor for about 0.5 seconds to about 3 seconds, the oxidizing agent for about 0.5 seconds to about 3 seconds, and the pump-purge for about 1 second to about 10 seconds.

Each ALD cycle is repeated from 2, 3, 4, 5, 6, 8, about 10, about 12, or about 15 times to about 18, about 20, about 25, about 30, about 40, about 50, about 65, about 80, about 100, about 120, about 150, about 200, about 250, about 300, about 350, about 400, about 500, about 800, about 1,000, about 1,500, about 2,000, about 2,500, about 3,000, about 4,000, about 5,000, or more times to form the cerium oxide layer. For example, each ALD cycle is repeated from 2 times to about 5,000 times, 2 times to about 3,000 times, 2 times to about 2,500 times, 2 times to about 2,000 times, 2 times to about 1,500 times, 2 times to about 1,000 times, 2 times to about 800 times, 2 times to about 500 times, 2 times to about 300 times, 2 times to about 250 times, 2 times to about 200 times, 2 times to about 150 times, 2 times to about 120 times, 2 times to about 100 times, 2 times to about 80 times, 2 times to about 50 times, 2 times to about 30 times, 2 times to about 20 times, 2 times to about 15 times, 2 times to about 10 times, 2 times to 5 times, about 20 times to about 5,000 times, about 20 times to about 3,000 times, about 20 times to about 2,500 times, about 20 times to about 2,000 times, about 20 times to about 1,500 times, about 20 times to about 1,000 times, about 20 times to about 800 times, about 20 times to about 500 times, about 20 times to about 300 times, about 20 times to about 250 times, about 20 times to about 200 times, about 20 times to about 150 times, about 20 times to about 120 times, about 20 times to about 100 times, about 20 times to about 80 times, about 20 times to about 50 times, about 20 times to about 30 times, about 50 times to about 5,000 times, about 50 times to about 3,000 times, about 50 times to about 2,500 times, about 50 times to about 2,000 times, about 50 times to about 1,500 times, about 50 times to about 1,000 times, about 50 times to about 500 times, about 50 times to about 350 times, about 50 times to about 300 times, about 50 times to about 250 times, about 50 times to about 150 times, about 50 times to about 100 times, about 100 times to about 5,000 times, about 100 times to about 3,000 times, about 100 times to about 2,500 times, about 100 times to about 2,000 times, about 100 times to about 1,500 times, about 100 times to about 1,000 times, about 100 times to about 500 times, about 100 times to about 350 times, about 100 times to about 300 times, about 100 times to about 250 times, about 100 times to about 150 times, about 500 times to about 5,000 times, about 500 times to about 3,000 times, about 500 times to about 2,500 times, about 500 times to about 2,000 times, about 500 times to about 1,500 times, about 500 times to about 1,000 times to form the cerium oxide layer.

In one or more embodiments, the ALD cycle can be repeated until the cerium oxide layer has a predetermined or desired thickness. The cerium oxide layer can have a thickness of about 0.5 nm, about 1 nm, about 2 nm, about 5 nm, about 8 nm, about 10 nm, about 12 nm, about 15 nm, about 18 nm, or about 20 nm to about 22 nm, about 25 nm, about 30 nm, about 35 nm, about 40 nm, about 50 nm, about 60 nm, about 80 nm, about 100 nm, about 150 nm, about 200 nm, or greater. For example, the cerium oxide layer can have a thickness of about 1 nm to about 200 nm, about 1 nm to about 150 nm, about 1 nm to about 100 nm, about 1 nm to about 80 nm, about 1 nm to about 50 nm, about 1 nm to about 30 nm, about 1 nm to about 20 nm, about 1 nm to about 10 nm, about 1 nm to about 5 nm, about 10 nm to about 200 nm, about 10 nm to about 150 nm, about 10 nm to about 100 nm, about 10 nm to about 80 nm, about 10 nm to about 50 nm, about 10 nm to about 30 nm, about 10 nm to about 20 nm, about 20 nm to about 200 nm, about 20 nm to about 150 nm, about 20 nm to about 100 nm, about 20 nm to about 80 nm, about 20 nm to about 50 nm, about 20 nm to about 30 nm, or about 20 nm to about 25 nm.

### Protective Coating

The protective coating can have a thickness of about 1 nm, about 2 nm, about 3 nm, about 5 nm, about 8 nm, about 10 nm, about 12 nm, about 15 nm, about 20 nm, about 30 nm, about 50 nm, about 60 nm, about 80 nm, about 100 nm, or about 120 nm to about 150 nm, about 180 nm, about 200 nm, about 250 nm, about 300 nm, about 350 nm, about 400 nm, about 500 nm, about 800 nm, about 1,000 nm, about 2,000 nm, about 3,000 nm, about 4,000 nm, about 5,000 nm, about 6,000 nm, about 7,000 nm, about 8,000 nm, about 9,000 nm, about 10,000 nm, or thicker. In some examples, the protective coating can have a thickness of less than 10 μm (less than 10,000 nm). For example, the protective coating can have a thickness of about 1 nm to less than 10,000 nm, about 1 nm to about 8,000 nm, about 1 nm to about 6,000 nm, about 1 nm to about 5,000 nm, about 1 nm to about 3,000 nm, about 1 nm to about 2,000 nm, about 1 nm to about 1,500 nm, about 1 nm to about 1,000 nm, about 1 nm to about 500 nm, about 1 nm to about 400 nm, about 1 nm to about 300 nm, about 1 nm to about 250 nm, about 1 nm to about 200 nm, about 1 nm to about 150 nm, about 1 nm to about 100 nm, about 1 nm to about 80 nm, about 1 nm to about 50 nm, about 10 nm to less than 10,000 nm, about 10 nm to about 8,000 nm, about 10 nm to about 6,000 nm, about 10 nm to about 5,000 nm, about 10 nm to about 3,000 nm, about 10 nm to about 2,000 nm, about 10 nm to about 1,500 nm, about 10 nm to about 1,000 nm, about 10 nm to about 800 nm, about 10 nm to about 500 nm, about 10 nm to about 400 nm, about 10 nm to about 300 nm, about 10 nm to about 250 nm, about 10 nm to about 200 nm, about 10 nm to about 150 nm, about 10 nm to about 100 nm, about 10 nm to about 80 nm, about 10 nm to about 50 nm, about 30 nm to about 400 nm, about 30 nm to about 200 nm, about 50 nm to about 500 nm, about 50 nm to about 400 nm, about 50 nm to about 300 nm, about 50 nm to about 250 nm, about 50 nm to about 200 nm, about 50 nm to about 150 nm, about 50 nm to about 100 nm, about 80 nm to about 250 nm, about 80 nm to about 200 nm, about 80 nm to about 150 nm, about 80 nm to about 100 nm, about 50 nm to about 80 nm, about 100 nm to about 500 nm, about 100 nm to about 400 nm, about 100 nm to about 300 nm, about 100 nm to about 250 nm, about 100 nm to about 200 nm, or about 100 nm to about 150 nm.

In one or more embodiments, the protective coating can have a relatively high degree of uniformity. The protective coating can have a uniformity of less than 50%, less than 40%, or less than 30% of the thickness of the respective protective coating. The protective coating can have a uniformity from about 0%, about 0.5%, about 1%, about 2%, about 3%, about 5%, about 8%, or about 10% to about 12%, about 15%, about 18%, about 20%, about 22%, about 25%, about 28%, about 30%, about 35%, about 40%, about 45%, or less than 50% of the thickness. For example, the protective coating can have a uniformity from about 0% to about 50%, about 0% to about 40%, about 0% to about 30%, about 0% to less than 30%, about 0% to about 28%, about 0% to about 25%, about 0% to about 20%, about 0% to about 15%, about 0% to about 10%, about 0% to about 8%, about 0% to about 5%, about 0% to about 3%, about 0% to about 2%, about 0% to about 1%, about 1% to about 50%, about 1% to about 40%, about 1% to about 30%, about 1% to less than 30%, about 1% to about 28%, about 1% to about 25%, about 1% to about 20%, about 1% to about 15%, about 1% to about 10%, about 1% to about 8%, about 1% to about 5%, about 1% to about 3%, about 1% to about 2%, about 5% to about 50%, about 5% to about 40%, about 5% to about 30%, about 5% to less than 30%, about 5% to about 28%, about 5% to about 25%, about 5% to about 20%, about 5% to about 15%, about 5% to about 10%, about 5% to about 8%, about 10% to about 50%, about 10% to about 40%, about 10% to about 30%, about 10% to less than 30%, about 10% to about 28%, about 10% to about 25%, about 10% to about 20%, about 10% to about 15%, or about 10% to about 12% of the thickness.

In some embodiments, the protective coating can contain, be formed with, or otherwise produced with different ratios of metals throughout the material, such as one or more doping metals (e.g., gadolinium, manganese, strontium, cobalt, copper, aluminum, alloys thereof) and/or one or more grading metals contained within a base metal, where any of the metals can be in any chemically oxidized form or state (e.g., oxide, nitride, silicide, carbide, or combinations thereof). In one or more examples, the first deposited layer is deposited to first thickness and the second deposited layer is deposited to a second thickness. The first thickness can be the same as the second thickness or the first thickness can be different than (less than or greater than) the second thickness. For example, the first deposited layer can be deposited by two or more (3, 4, 5, 6, 7, 8, 9, 10, or more) ALD cycles to produce the respectively same amount of sub-layers (e.g., one sub-layer for each ALD cycle), and then the second deposited layer can be deposited by one ALD cycle or a number of ALD cycles that is less than or greater than the number of ALD cycles used to deposit the first deposited layer. In other examples, the first deposited layer can be deposited by CVD to a first thickness and the second deposited layer is deposited by ALD to a second thickness which is less than the first thickness.

In other embodiments, an ALD process can be used to deposit the first deposited layer (e.g., the barrier layer) and/or the second deposited layer (e.g., the catalytic oxidation layer) where the deposited material is doped by including a dopant precursor during the ALD process. In some examples, the dopant precursor can be included a separate ALD cycle relative to the ALD cycles used to deposit the base material. In other examples, the dopant precursor can be co-injected with any of the chemical precursors used during the ALD cycle. In further examples, the dopant precursor can be injected separate from the chemical precursors during the ALD cycle. For example, one ALD cycle can include exposing the aerospace component to: the first precursor, a pump-purge, the dopant precursor, a pump-purge, the first reactant, and a pump-purge to form the deposited layer. In some examples, one ALD cycle can include exposing the aerospace component to: the dopant precursor, a pump-purge, the first precursor, a pump-purge, the first reactant, and a pump-purge to form the deposited layer. In other examples, one ALD cycle can include exposing the aerospace component to: the first precursor, the dopant precursor, a pump-purge, the first reactant, and a pump-purge to form the deposited layer.

The doping material can have a concentration of about 0.01 atomic percent (at %), about 0.05 at %, about 0.08 at %, about 0.1 at %, about 0.5 at %, about 0.8 at %, about 1 at %, about 1.2 at %, about 1.5 at %, about 1.8 at %, or about 2 at % to about 2.5 at %, about 3 at %, about 3.5 at %, about 4 at %, about 5 at %, about 8 at %, about 10 at %, about 15 at %, about 20 at %, about 25 at %, or about 30 at % within the barrier layer (or the first deposited layer), the catalytic oxidation layer (or the second deposited layer), and/or the protective coating. For example, the doping material can have a concentration of about 0.01 at % to about 30 at %, about 0.01 at % to about 25 at %, about 0.01 at % to about 20 at %, about 0.01 at % to about 15 at %, about 0.01 at % to about 12 at %, about 0.01 at % to about 10 at %, about 0.01 at % to about 8 at %, about 0.01 at % to about 5 at %, about 0.01 at % to about 4 at %, about 0.01 at % to about 3 at %, about 0.01 at % to about 2.5 at %, about 0.01 at % to about 2 at %, about 0.01 at % to about 1.5 at %, about 0.01 at % to about 1 at %, about 0.01 at % to about 0.5 at %, about 0.01 at % to about 0.1 at %, about 0.1 at % to about 30 at %, about 0.1 at % to about 25 at %, about 0.1 at % to about 20 at %, about 0.1 at % to about 15 at %, about 0.1 at % to about 12 at %, about 0.1 at % to about 10 at %, about 0.1 at % to about 8 at %, about 0.1 at % to about 5 at %, about 0.1 at % to about 4 at %, about 0.1 at % to about 3 at %, about 0.1 at % to about 2.5 at %, about 0.1 at % to about 2 at %, about 0.1 at % to about 1.5 at %, about 0.1 at % to about 1 at %, about 0.1 at % to about 0.5 at %, about 1 at % to about 30 at %, about 1 at % to about 25 at %, about 1 at % to about 20 at %, about 1 at % to about 15 at %, about 1 at % to about 12 at %, about 1 at % to about 10 at %, about 1 at % to about 8 at %, about 1 at % to about 5 at %, about 1 at % to about 4 at %, about 1 at % to about 3 at %, about 1 at % to about 2.5 at %, about 1 at % to about 2 at %, or about 1 at % to about 1.5 at % within the barrier layer (or the first deposited layer), the catalytic oxidation layer (or the second deposited layer), and/or the protective coating.

Aerospace components as described and discussed herein, including aerospace component, can be or include one or more components or portions thereof of a fuel system, a turbine, an aircraft, a spacecraft, or other devices that can include one or more turbines (e.g., compressors, pumps, turbo fans, super chargers, and the like). Exemplary aerospace components can be or include a fuel nozzle, a combustor liner, a combustor shield, a heat exchanger, a fuel line, a fuel valve, any other part or portion that is exposed to a fuel (e.g., aviation fuel or jet fuel), as well as one or more turbine blades, turbine vanes, ribs, fins, pin fins, an internal cooling channel, or any other aerospace component or part that can benefit from having protective coating deposited thereon, or any combination thereof.

The aerospace component has one, two, or more outer or exterior surfaces and one or more inner or interior surfaces. The protective coating can be deposited or otherwise formed on interior surfaces and/or exterior surfaces of the aerospace components. The interior surfaces can define one or more cavities extending or contained within the aerospace component. The cavities can be channels, passages, spaces, or the like disposed between the interior surfaces. The cavity can have one or more openings. Each of the cavities within the aerospace component typically have an aspect ratio (e.g., length divided by width) of greater than 1. Embodiments of methods described and discussed herein provide cleaning surfaces within the cavities, as well as depositing and/or otherwise forming the protective coating on the interior surfaces, including cleaned surfaces, within these cavities having high aspect ratios (greater than 1).

The aspect ratio of the cavity within the aerospace component can be from greater than 1, about 1.5 about 2, about 3, about 5, about 8, about 10, or about 12 to about 15, about 20, about 25, about 30, about 40, about 50, about 65, about 80, about 100, about 120, about 150, about 200, about 250, about 300, about 500, about 800, about 1,000, or greater. For example, the aspect ratio of the cavity within the aerospace component can be from about 2 to about 1,000, about 2 to about 500, about 2 to about 200, about 2 to about 150, about 2 to about 120, about 2 to about 100, about 2 to about 80, about 2 to about 50, about 2 to about 40, about 2 to about 30, about 2 to about 20, about 2 to about 10, about 2 to about 8, about 5 to about 1,000, about 5 to about 500, about 5 to about 200, about 5 to about 150, about 5 to about 120, about 5 to about 100, about 5 to about 80, about 5 to about 50, about 5 to about 40, about 5 to about 30, about 5 to about 20, about 5 to about 10, about 5 to about 8, about 10 to about 1,000, about 10 to about 500, about 10 to about 200, about 10 to about 150, about 10 to about 120, about 10 to about 100, about 10 to about 80, about 10 to about 50, about 10 to about 40, about 10 to about 30, about 10 to about 20, about 20 to about 1,000, about 20 to about 500, about 20 to about 200, about 20 to about 150, about 20 to about 120, about 20 to about 100, about 20 to about 80, about 20 to about 50, about 20 to about 40, or about 20 to about 30.

The aerospace component and any surface thereof including one or more outer or exterior surfaces and/or one or more inner or interior surfaces can be made of, contain, or otherwise include one or more metals, such as nickel, chromium, cobalt, chromium-cobalt alloys, molybdenum, iron, titanium, one or more nickel superalloys, one or more Inconel alloys, one or more Hastelloy alloys, one or more Invar alloys, one or more Inovoco alloys, alloys thereof, or any combination thereof. The protective coating can be deposited, formed, or otherwise produced on any surface of the aerospace component including one or more outer or exterior surfaces and/or one or more inner or interior surfaces.

The protective coating, as described and discussed herein, can be or include mono-layer films, two or more layered films (e.g., multi-layered films), monolithic films, laminate film stacks, coalesced films, crystalline film, graded compositions, and/or combinations thereof, which are deposited or otherwise formed on any surface of an aerospace component. In some examples, the protective coating contains one or more catalytic oxidation layers and optionally one or more barrier layers disposed between the aerospace component and the catalytic oxidation layer. The protective coating is conformal and substantially coat rough surface features following surface topology, including in open pores, blind holes, and non-line-of sight regions of a surface. The protective coating does not substantially increase surface roughness, and in some embodiments, the protective coating may reduce surface roughness by conformally coating roughness until it coalesces. The protective coating may contain particles from the deposition that are substantially larger than the roughness of the aerospace component, but are considered separate from the monolithic film. The protective coating is substantially well adhered and pinhole free. The thicknesses of the protective coating can vary within 1-sigma of 40%. In one or more embodiments, the thickness varies less than 1-sigma of 20%, 10%, 5%, 1%, or 0.1%.

In addition to providing protection against coke deposition, the protective coating provides corrosion and oxidation protection when the aerospace components are exposed to air, oxygen, sulfur and/or sulfur compounds, acids, bases, salts (e.g., Na, K, Mg, Li, or Ca salts), or any combination thereof. The aerospace component may be exposed to these conditions during normal operation or during a cleaning process to remove any carbon buildup.

The aerospace component containing the protective coating is heated to an operating temperature during use to burn-off, oxidize, or otherwise remove coke, fuel, particulates, and/or other non-desired materials or debris on the aerospace component during operation (e.g., running a jet or turbine engine having one or more of the aerospace components). The operating temperature of the aerospace component containing the protective coating is about 200° C., about 300° C., about 400° C., about 500° C., or about 550° C. to about 600° C., about 650° C., about 700° C., about 750° C., about 800° C., about 900° C., about 1,000° C., or greater during an operation or use. For example, the aerospace component containing the protective coating is heated to a temperature of about 200° C. to about 1,000° C., about 200° C. to about 900° C., about 200° C. to about 800° C., about 200° C. to about 700° C., about 200° C. to about 650° C., about 200° C. to about 600° C., about 200° C. to about 550° C., about 200° C. to about 500° C., about 200° C. to about 450° C., about 200° C. to about 400° C., about 200° C. to about 300° C., about 400° C. to about 1,000° C., about 400° C. to about 900° C., about 400° C. to about 800° C., about 400° C. to about 700° C., about 400° C. to about 650° C., about 400° C. to about 600° C., about 400° C. to about 550° C., about 400° C. to about 500° C., about 400° C. to about 450° C., about 500° C. to about 1,000° C., about 500° C. to about 900° C., about 500° C. to about 800° C., about 500° C. to about 700° C., about 500° C. to about 650° C., about 500° C. to about 600° C., or about 500° C. to about 550° C. during an operation or use.

Embodiments of the present disclosure further relate to any one or more of the following paragraphs 1-34:

1. A method for depositing a protective coating on an aerospace component, comprising: depositing a barrier layer on a surface of the aerospace component; and depositing a catalytic oxidation layer on the barrier layer.

2. A method for depositing a protective coating on an aerospace component, comprising: depositing a catalytic oxidation layer comprising cerium oxide on a surface of the aerospace component by an atomic layer deposition (ALD) process, wherein: the aerospace component is a fuel nozzle, a combustor liner, a combustor shield, a heat exchanger, a fuel line, a fuel valve, or any combination thereof; the surface of the aerospace component has an aspect ratio of about 5 to about 1,000; and the catalytic oxidation layer has a thickness of about 10 nm to about 500 nm.

3. An aerospace component, comprising: a protective coating disposed on a surface of the aerospace component, wherein the protective coating comprises: a barrier layer comprising aluminum oxide, magnesium-doped aluminum oxide, dopants thereof, or any combination thereof disposed on the surface of the aerospace component; and a catalytic oxidation layer comprising cerium oxide, zirconium oxide, calcium aluminum manganese oxide, barium yttrium manganese oxide, lanthanum rhodium manganese oxide, lutetium iron oxide, yttrium barium cobalt oxide, lanthanum oxide sulfate, dopants thereof, or any combination thereof disposed on the barrier layer.

4. An aerospace component, comprising: a protective coating disposed on a surface of the aerospace component, wherein the protective coating comprises: a barrier layer comprising aluminum oxide disposed on the surface of the aerospace component; and a catalytic oxidation layer comprising cerium oxide disposed on the barrier layer.

5. The method and/or the aerospace component according to any one of paragraphs 1-4, wherein the barrier layer comprises aluminum oxide, magnesium-doped aluminum oxide, dopants thereof, or any combination thereof.

6. The method and/or the aerospace component according to any one of paragraphs 1-5, wherein the barrier layer is deposited by an ALD process.

7. The method and/or the aerospace component according to paragraph 6, wherein the ALD process comprises sequentially exposing the aerospace component to an aluminum precursor and an oxidizing agent.

8. The method and/or the aerospace component according to paragraph 7, wherein the aluminum precursor comprises a tris(alkyl) aluminum, a tris(alkoxy) aluminum, aluminum diketonates, complexes thereof, abducts thereof, salts thereof, or any combination thereof.

9. The method and/or the aerospace component according to paragraph 7, wherein the oxidizing agent comprises water, ozone, oxygen (02), atomic oxygen, nitrous oxide, a peroxide, an alcohol, a plasma thereof, or any combination thereof.

10. The method and/or the aerospace component according to any one of paragraphs 1-9, wherein the barrier layer has a thickness of about 1 nm to about 500 nm.

11. The method and/or the aerospace component according to any one of paragraphs 1-10, wherein the barrier layer has a thickness of about 5 nm to about 250 nm.

12. The method and/or the aerospace component according to any one of paragraphs 1-11, wherein the barrier layer has a thickness of about 10 nm to about 100 nm.

13. The method and/or the aerospace component according to any one of paragraphs 1-12, wherein the catalytic oxidation layer comprises cerium oxide, zirconium oxide, calcium aluminum manganese oxide, barium yttrium manganese oxide, lanthanum rhodium manganese oxide, lutetium iron oxide, yttrium barium cobalt oxide, lanthanum oxide sulfate, dopants thereof, or any combination thereof.

14. The method and/or the aerospace component according to any one of paragraphs 1-13, wherein the catalytic oxidation layer comprises cerium oxide and a dopant, and wherein the dopant comprises gadolinium, manganese, strontium, cobalt, copper, aluminum, alloys thereof, oxides thereof, or any combination thereof.

15. The method and/or the aerospace component according to any one of paragraphs 1-14, wherein the catalytic oxidation layer comprises cerium oxide deposited by an ALD process.

16. The method and/or the aerospace component according to paragraph 15, wherein the ALD process comprises repeating an ALD cycle until the catalytic oxidation layer has a thickness of about 10 nm to about 500 nm.

17. The method and/or the aerospace component according to any one of paragraphs 1-16, wherein the catalytic oxidation layer has a thickness of about 20 nm to about 100 nm.

18. The method and/or the aerospace component according to any one of paragraphs 1-17, wherein the catalytic oxidation layer has a thickness of about 50 nm to about 80 nm.

19. The method and/or the aerospace component according to any one of paragraphs 1-18, wherein the cerium precursor comprises a cerium β-diketonate compound, a cerium cyclopentadienyl compound, a cerium alkoxide compound, a cerium amide compound, a cerium acetamidinate compound, an adduct thereof, or any combination thereof.

20. The method and/or the aerospace component according to paragraph 19, wherein the cerium precursor comprises a cerium β-diketonate compound.

21. The method and/or the aerospace component according to paragraph 20, wherein the cerium β-diketonate compound is Ce(thd)₄, Ce(thd)₃, Ce(thd)₃(phen), an adduct thereof, or any combination thereof.

22. The method and/or the aerospace component according to paragraph 19, wherein the cerium precursor comprises a cerium cyclopentadienyl compound.

23. The method and/or the aerospace component according to paragraph 22, wherein the cerium cyclopentadienyl compound is (Cp)₃Ce, (MeCp)₃Ce, (EtCp)₃Ce, (PrCp)₃Ce, (BuCp)₃Ce, an adduct thereof, or any combination thereof.

24. The method and/or the aerospace component according to paragraph 19, wherein the cerium precursor comprises a cerium alkoxide compound.

25. The method and/or the aerospace component according to paragraph 24, wherein the cerium alkoxide compound is Ce(mmp)₄ (cerium tetra(1-methoxy-2-methyl-2-propanolate)), Ce(dmap)₄ (cerium tetra(1-(dimethylamino)propan-2-olate)), Ce(dmop)₄ (cerium tetra(2-(4,4-dimethyl-4,5-dihydrooxazol-2-yl)propan-2-olate)), an adduct thereof, or any combination thereof.

26. The method and/or the aerospace component according to paragraph 19, wherein the cerium precursor comprises a cerium amide compound or a cerium acetamidinate compound.

27. The method and/or the aerospace component according to paragraph 26, wherein the cerium precursor is (hmdsa)₃Ce or (′PrCp)₂Ce(N-′Pr-amd).

28. The method and/or the aerospace component according to any one of paragraphs 1-27, wherein the aerospace component is a fuel nozzle, a combustor liner, a combustor shield, a heat exchanger, a fuel line, a fuel valve, or any combination thereof.

29. The method and/or the aerospace component according to any one of paragraphs 1-28, wherein the surface of the aerospace component is an interior surface of the aerospace component, and wherein the surface of the aerospace component has an aspect ratio of about 5 to about 1,000.

30. The method and/or the aerospace component according to any one of paragraphs 1-29, wherein the cleaned surface of the aerospace component comprises nickel, nickel superalloy, stainless steel, cobalt, chromium, molybdenum, iron, titanium, alloys thereof, or any combination thereof.

31. The method and/or the aerospace component according to any one of paragraphs 1-30, wherein the protective coating reduces or suppresses coke formation when the aerospace component is heated in the presence of a fuel.

32. The method and/or the aerospace component according to any one of paragraphs 1-31, wherein the protective coating has a thickness of about 10 nm to about 5,000 nm.

33. The method and/or the aerospace component according to any one of paragraphs 1-32, wherein the protective coating has a thickness variation of less than 5%.

34. An aerospace component comprising the protective coating formed by the method according to any one of paragraphs 1-33.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise whenever a composition, an element or a group of elements is preceded with the transitional phrase “comprising”, it is understood that we also contemplate the same composition or group of elements with transitional phrases “consisting essentially of,” “consisting of”, “selected from the group of consisting of,” or “is” preceding the recitation of the composition, element, or elements and vice versa.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

1. A method for depositing a protective coating on an aerospace component, comprising:
depositing a barrier layer on a surface of the aerospace component; and
depositing a catalytic oxidation layer comprising cerium on the barrier layer.

2. The method of claim 1, wherein the barrier layer comprises aluminum oxide, magnesium-doped aluminum oxide, dopants thereof, or any combination thereof.

3. The method of claim 1, wherein the barrier layer is deposited by an atomic layer deposition (ALD) process, and wherein the ALD process comprises sequentially exposing the aerospace component to an aluminum precursor and an oxidizing agent.

4. The method of claim 3, wherein the aluminum precursor comprises a tris(alkyl) aluminum, a tris(alkoxy) aluminum, aluminum diketonates, complexes thereof, abducts thereof, salts thereof, or any combination thereof, and wherein the oxidizing agent comprises water, ozone, oxygen (O₂), atomic oxygen, nitrous oxide, a peroxide, an alcohol, a plasma thereof, or any combination thereof.

5. The method of claim 1, wherein the barrier layer has a thickness of about 5 nm to about 250 nm.

6. The method of claim 1, wherein the catalytic oxidation layer comprises cerium oxide, zirconium oxide, calcium aluminum manganese oxide, barium yttrium manganese oxide, lanthanum rhodium manganese oxide, lutetium iron oxide, yttrium barium cobalt oxide, lanthanum oxide sulfate, dopants thereof, or any combination thereof.

7. The method of claim 1, wherein the catalytic oxidation layer comprises cerium oxide and a dopant, and wherein the dopant comprises gadolinium, manganese, strontium, cobalt, copper, aluminum, alloys thereof, oxides thereof, or any combination thereof.

8. The method of claim 1, wherein the catalytic oxidation layer comprises cerium oxide deposited by an atomic layer deposition (ALD) process, wherein the ALD process comprises sequentially exposing the aerospace component to a cerium precursor and an oxidizing agent during an ALD cycle, and wherein the ALD process comprises repeating the ALD cycle until the catalytic oxidation layer has a thickness of about 10 nm to about 500 nm.

9. The method of claim 1, wherein the catalytic oxidation layer has a thickness of about 20 nm to about 100 nm.

10. The method of claim 8, wherein the cerium precursor comprises a cerium β-diketonate compound, a cerium cyclopentadienyl compound, a cerium alkoxide compound, a cerium amide compound, a cerium acetamidinate compound, an adduct thereof, or any combination thereof.

11. The method of claim 10, wherein the cerium precursor comprises a cerium β-diketonate compound, and wherein the cerium β-diketonate compound is Ce(thd)₄, Ce(thd)₃, Ce(thd)₃(phen), an adduct thereof, or any combination thereof.

12. The method of claim 10, wherein the cerium precursor comprises a cerium cyclopentadienyl compound, and wherein the cerium cyclopentadienyl compound is (Cp)₃Ce, (MeCp)₃Ce, (EtCp)₃Ce, (PrCp)₃Ce, (BuCp)₃Ce, an adduct thereof, or any combination thereof.

13. The method of claim 10, wherein the cerium precursor comprises a cerium alkoxide compound, and wherein the cerium alkoxide compound is Ce(mmp)₄ (cerium tetra(1-methoxy-2-methyl-2-propanolate)), Ce(dmap)₄ (cerium tetra(1-(dimethylamino)propan-2-olate)), Ce(dmop)₄ (cerium tetra(2-(4,4-dimethyl-4,5-dihydrooxazol-2-yl)propan-2-olate)), an adduct thereof, or any combination thereof.

14. The method of claim 10, wherein the cerium precursor comprises a cerium amide compound or a cerium acetamidinate compound, and wherein the cerium precursor is (hmdsa)₃Ce or (ⁱPrCp)₂Ce(N-ⁱPr-amd).

15. The method of claim 1, wherein the aerospace component is a fuel nozzle, a combustor liner, a combustor shield, a heat exchanger, a fuel line, a fuel valve, or any combination thereof, wherein the protective coating is deposited on a surface of the aerospace component, and wherein the surface comprises nickel, nickel superalloy, stainless steel, cobalt, chromium, molybdenum, iron, titanium, alloys thereof, or any combination thereof.

16. The method of claim 1, wherein the protective coating is deposited on a surface of the aerospace component, wherein the surface is an interior surface of the aerospace component, and wherein the surface of the aerospace component has an aspect ratio of about 5 to about 1,000.

17. The method of claim 1, wherein the protective coating reduces or suppresses coke formation when the aerospace component is heated in the presence of a fuel.

18. The method of claim 1, wherein the protective coating has a thickness of about 10 nm to about 5,000 nm and a thickness variation of less than 5%.

19. A method for depositing a protective coating on an aerospace component, comprising:
depositing a catalytic oxidation layer comprising cerium oxide on a surface of the aerospace component by an atomic layer deposition (ALD) process, wherein:
the aerospace component is a fuel nozzle, a combustor liner, a combustor shield, a heat exchanger, a fuel line, a fuel valve, or any combination thereof;
the surface of the aerospace component is an interior surface of the aerospace component and has an aspect ratio of about 5 to about 1,000; and
the catalytic oxidation layer has a thickness of about 10 nm to about 500 nm.

20. An aerospace component, comprising:
a protective coating disposed on an interior surface of the aerospace component, wherein the protective coating comprises:
a barrier layer comprising aluminum oxide disposed on the interior surface of the aerospace component; and
a catalytic oxidation layer comprising cerium oxide disposed on the barrier layer.
